(19) United States
(12) Patent Application Publication
(10) Pub. No.: US 2026/0303063 A1
(43) Pub. Date: Oct. 1, 2026

(54) MULTIPLEXER AND FILTER DEVICE

(71) Applicant: Murata Manufacturing Co., Ltd., Nagaokakyo-shi (JP)

(72) Inventor: Shiori ASAKAWA, Nagaokakyo-shi (JP)

(21) Appl. No.: 19/632,698

(22) Filed: Mar. 30, 2026

(30) Foreign Application Priority Data
Mar. 31, 2025 (JP) 2025-059552

(51) Int. Cl. H03H 9/60; H03H 9/13; H03H 9/205; H03H 9/70

(52) U.S. Cl. CPC H03H 9/605; H03H 9/133; H03H 9/205; H03H 9/70

(57) ABSTRACT

A multiplexer includes a transmission filter including a first reference potential electrode connected to a first reference potential terminal and located closer to a reference potential than a capacitor, a first external reference potential electrode electrically connected to a first reference potential electrode, a second reference potential electrode connected to a second reference potential terminal and located closer to the reference potential than the capacitor, a second external reference potential electrode electrically connected to the second reference potential electrode, and an inductor connected between the second reference potential electrode and the second external reference potential electrode, and a reception filter. A total inductance between the first reference potential electrode and the first external reference potential electrode is less than a total inductance between the second reference potential electrode and the second external reference potential electrode.

### CROSS REFERENCE TO RELATED APPLICATIONS

This application claims the benefit of priority to Japanese Patent Application No. 2025-059552 filed on Mar. 31, 2025. The entire contents of this application are hereby incorporated herein by reference.

### BACKGROUND OF THE INVENTION

### 1. Field of the Invention

The present invention relates to multiplexers and filter devices including acoustic wave resonators.

### 2. Description of the Related Art

Filter devices and multiplexers are widely used, for example, as filters in mobile phones. International Publication No. 2012/063516 discloses an acoustic wave filter device including a transmission-side filter unit and a reception-side filter unit. In the transmission-side filter unit of the acoustic wave filter device, a plurality of parallel-arm resonators are commonly connected to the ground potential.

When a plurality of parallel-arm resonators are commonly connected to the ground potential as in the transmission-side filter unit of International Publication No. 2012/063516, the inductance tends to become high in the paths from the plurality of parallel-arm resonators to the ground potential. Therefore, there is a possibility that a portion of a signal passing through a parallel-arm resonator does not flow to the external ground potential and cannot be sufficiently prevented from leaking into the output side via another parallel-arm resonator. This in turn makes it difficult to sufficiently increase the out-of-band attenuation of the transmission-side filter unit and to sufficiently improve the isolation of the acoustic wave filter device.

### SUMMARY OF THE INVENTION

Example embodiments of the present invention provide multiplexers each with improved isolation, and filter devices each with increased out-of-band attenuation.

A multiplexer according to an example embodiment of the present invention includes a transmission filter including an input terminal and an output terminal, a first reference potential terminal and a second reference potential terminal connected to a reference potential, a first parallel-arm resonator connected to the first reference potential terminal, a plurality of second parallel-arm resonators located closer to the output terminal than the first parallel-arm resonator in a circuit configuration and commonly connected to the second reference potential terminal, a capacitor connected between the first reference potential terminal and the second reference potential terminal, a first reference potential electrode connected to the first reference potential terminal and located closer to the reference potential than the capacitor, a first external reference potential electrode electrically connected to the first reference potential electrode, a second reference potential electrode connected to the second reference potential terminal and located closer to the reference potential than the capacitor, a second external reference potential electrode electrically connected to the second reference potential electrode, and an inductor connected between the second reference potential electrode and the second external reference potential electrode, and a reception filter. A total inductance between the first reference potential electrode and the first external reference potential electrode is less than a total inductance between the second reference potential electrode and the second external reference potential electrode.

A filter device according to an example embodiment of the present invention includes an input terminal and an output terminal, a first reference potential terminal and a second reference potential terminal connected to a reference potential, a first parallel-arm resonator connected to the first reference potential terminal, a plurality of second parallel-arm resonators located closer to the output terminal than the first parallel-arm resonator in a circuit configuration and being commonly connected to the second reference potential terminal, a capacitor connected between the first reference potential terminal and the second reference potential terminal, a first reference potential electrode connected to the first reference potential terminal and located closer to the reference potential than the capacitor, a first external reference potential electrode electrically connected to the first reference potential electrode, a second reference potential electrode connected to the second reference potential terminal and located closer to the reference potential than the capacitor, a second external reference potential electrode electrically connected to the second reference potential electrode, and an inductor connected between the second reference potential electrode and the second external reference potential electrode. A total inductance between the first reference potential electrode and the first external reference potential electrode is less than a total inductance between the second reference potential electrode and the second external reference potential electrode.

Example embodiments of the present invention provide multiplexers each with improved isolation, and filter devices each with increased out-of-band attenuation.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram of a multiplexer according to a first example embodiment of the present invention.

FIG. 2 is a circuit diagram of a multiplexer according to a first comparative example.

FIG. 3 is a diagram showing isolation of the multiplexers according to the first example embodiment of the present invention and the first comparative example.

FIG. 4 is a diagram schematically illustrating examples of paths through which portions of a signal are transmitted when the signal is input to a transmission filter according to the first example embodiment of the present invention.

FIG. 5 is a diagram schematically illustrating examples of paths through which portions of a signal are transmitted when the signal is input to a transmission filter according to the first comparative example.

FIG. 6 is a diagram showing a relationship between isolation and the electrostatic capacitance between a first reference potential terminal and a second reference potential terminal.

FIG. 7 is a diagram showing a relationship between isolation near 1855 MHz and the electrostatic capacitance between the first reference potential terminal and the second reference potential terminal.

FIG. 8 is a schematic plan view of the transmission filter according to the first example embodiment of the present invention.

FIG. 9 is a schematic plan view of a series-arm resonator of the transmission filter according to the first example embodiment of the present invention.

FIG. 10 is an enlarged schematic plan view of a portion around a capacitor of the transmission filter according to the first example embodiment of the present invention.

FIG. 11 is a schematic cross-sectional view taken along line I-I in FIG. 10.

FIG. 12 is a schematic cross-sectional view taken along line II-II in FIG. 10.

FIG. 13 is a schematic plan view for describing the positional relationship between a first parallel-arm resonator and a capacitor according to the first example embodiment of the present invention.

FIG. 14 is an enlarged schematic plan view of a portion around a capacitor of a transmission filter according to a first variation of the first example embodiment of the present invention.

FIG. 15 is a schematic cross-sectional view taken along line I-I in FIG. 14.

FIG. 16 is a schematic plan view of a transmission filter according to a second variation of the first example embodiment of the present invention.

FIG. 17 is a schematic cross-sectional view taken along line III-III in FIG. 16.

FIG. 18 is a schematic cross-sectional view showing a cross section that passes through the first reference potential terminal and the second reference potential terminal of the multiplexer according to the first example embodiment of the present invention.

FIG. 19 is a circuit diagram of a multiplexer according to a second example embodiment of the present invention.

FIGS. 20A and 20B are schematic plan views for describing examples of methods for measuring the total length of a plurality of electrodes.

FIG. 20C is a schematic transparent plan view for describing an example of a method for measuring the total length of a plurality of electrodes.

FIG. 20D is a schematic cross-sectional view for describing an example of a method for measuring the total length of a plurality of electrodes.

FIG. 21 is a schematic cross-sectional view showing a cross section that passes through a first reference potential terminal and a second reference potential terminal of a multiplexer according to a third example embodiment of the present invention.

### DETAILED DESCRIPTION OF THE EXAMPLE EMBODIMENTS

Hereafter, example embodiments of the present invention are described in detail with reference to the drawings to clarify the present invention.

The example embodiments described in the present specification are examples, and partial replacement or a combination of components in different example embodiments may be made.

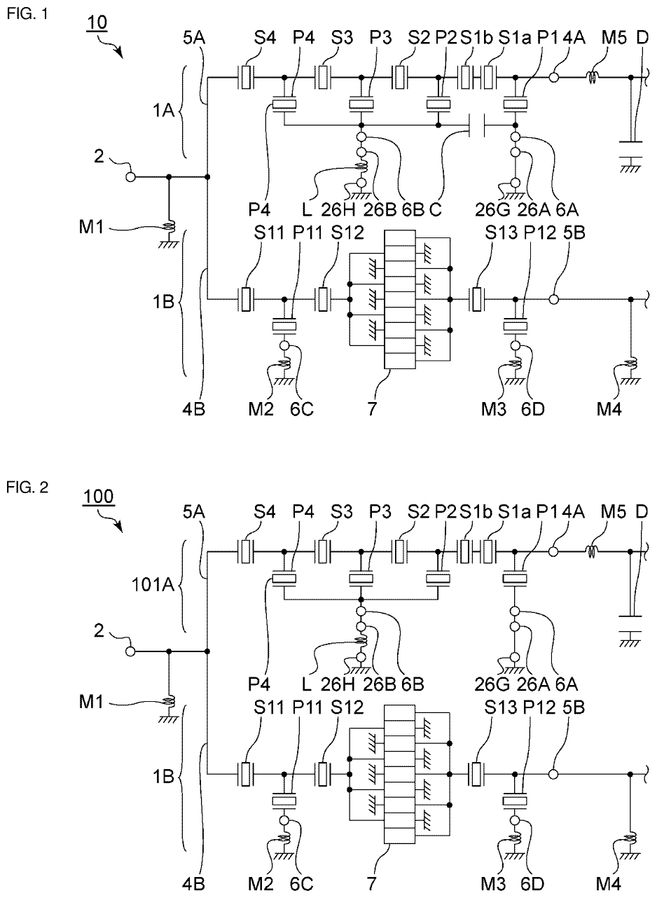

FIG. 1 is a circuit diagram of a multiplexer according to a first example embodiment of the present invention.

A multiplexer 10 of the present example embodiment is a duplexer, for example. The multiplexer 10 includes a common connection terminal 2, a transmission filter 1A, and a reception filter 1B. The transmission filter 1A and the reception filter 1B are commonly connected to the common connection terminal 2. In the present example embodiment, the common connection terminal 2 is an antenna terminal. The antenna terminal is connected to an antenna.

The multiplexer according to the present example embodiment is not limited to a duplexer. A multiplexer according to an example embodiment of the present invention may be, for example, a triplexer or a quadplexer. A multiplexer according to an example embodiment of the present invention only needs to include at least one transmission filter and at least one reception filter.

The transmission filter 1A of the multiplexer 10 illustrated in FIG. 1 is a filter device according to an example embodiment of the present invention. Specifically, the transmission filter 1A includes a first input terminal 4A, a first output terminal 5A, a plurality of resonators, a first reference potential terminal 6A, and a second reference potential terminal 6B. The transmission filter 1A further includes a first reference potential electrode 26A, a second reference potential electrode 26B, a first external reference potential electrode 26G, a second external reference potential electrode 26H, and an inductor L.

In the present specification, a reference potential terminal refers to a terminal that is connected to the reference potential. A reference potential electrode is an electrode that is connected to the reference potential terminal and is also connected to the reference potential. An external reference potential electrode is the most external electrode that is closest to the reference potential among electrodes that are electrically connected to the reference potential electrode and connected to the reference potential. That is, the external reference potential electrode is disposed closer to the reference potential than the reference potential electrode.

The reception filter 1B includes a second input terminal 4B, a second output terminal 5B, a plurality of resonators, a reference potential terminal 6C, and a reference potential terminal 6D.

Each of the terminals described above may be defined by an electrode pad or a wire, for example. Each of the reference potential electrodes and the external reference potential electrodes described above may be defined by an electrode pad or a wire, for example. In the present example embodiment, the common connection terminal 2, the first input terminal 4A, the second output terminal 5B, the first reference potential terminal 6A, the second reference potential terminal 6B, the reference potential terminal 6C, and the reference potential terminal 6D are defined by electrode pads, for example. The first reference potential electrode 26A, the second reference potential electrode 26B, the first external reference potential electrode 26G, and the second external reference potential electrode 26H are also defined by electrode pads, for example. On the one hand, the first output terminal 5A and the second input terminal 4B are defined by wires, for example. The first output terminal 5A and the second input terminal 4B are connected to the common connection terminal 2.

The transmission filter 1A is a ladder filter. The transmission filter 1A includes a plurality of series-arm resonators and a plurality of parallel-arm resonators. In the present example embodiment, the plurality of series-arm resonators and the plurality of parallel-arm resonators of the transmission filter 1A are all acoustic wave resonators, for example.

Specifically, the plurality of series-arm resonators of the transmission filter 1A include a series-arm resonator S1a, a series-arm resonator S1b, a series-arm resonator S2, a series-arm resonator S3, and a series-arm resonator S4. The plurality of series-arm resonators are connected in series with each other between the first input terminal 4A and the first output terminal 5A. More specifically, in terms of circuit configuration, the series-arm resonator S1a, the series-arm resonator S1b, the series-arm resonator S2, the series-arm resonator S3, and the series-arm resonator S4 are arranged in this order from the side of the first input terminal 4A.

Specifically, the plurality of parallel-arm resonators of the transmission filter 1A include a parallel-arm resonator P1, a parallel-arm resonator P2, a parallel-arm resonator P3, and a parallel-arm resonator P4. The parallel-arm resonator P1 is a first parallel-arm resonator. The parallel-arm resonator P2, the parallel-arm resonator P3, and the parallel-arm resonator P4 are a plurality of second parallel-arm resonators. In terms of circuit configuration, the plurality of second parallel-arm resonators are disposed closer to the first output terminal 5A than the first parallel-arm resonator.

More specifically, the parallel-arm resonator P1 is connected between the first input terminal 4A and the first reference potential terminal 6A. The parallel-arm resonator P2 is connected between the second reference potential terminal 6B and a connection point between the series-arm resonator S1b and the series-arm resonator S2. The parallel-arm resonator P3 is connected between the second reference potential terminal 6B and a connection point between the series-arm resonator S2 and the series-arm resonator S3. The parallel-arm resonator P4 is connected between the second reference potential terminal 6B and a connection point between the series-arm resonator S3 and the series-arm resonator S4. The parallel-arm resonator P2, the parallel-arm resonator P3, and the parallel-arm resonator P4, which are the plurality of second parallel-arm resonators, are commonly connected to the same second reference potential terminal 6B. On the other hand, the parallel-arm resonator P1, which is the first parallel-arm resonator, is connected to the first reference potential terminal 6A, which is not shared with other parallel-arm resonators.

A capacitor C is connected between the first reference potential terminal 6A and the second reference potential terminal 6B. The first reference potential terminal 6A is also connected to the first reference potential electrode 26A. Specifically, the first reference potential electrode 26A is disposed closer to the reference potential than the capacitor C. The first reference potential electrode 26A is electrically connected to the first external reference potential electrode 26G. The second reference potential terminal 6B is connected to the second reference potential electrode 26B. Specifically, the second reference potential electrode 26B is disposed closer to the reference potential than the capacitor C. The second reference potential electrode 26B is electrically connected to the second external reference potential electrode 26H. More specifically, the inductor L is connected between the second reference potential electrode 26B and the second external reference potential electrode 26H.

However, the circuit configuration of the transmission filter 1A is not limited to the example described above. As long as the first parallel-arm resonator is connected to the first reference potential terminal 6A and the plurality of second parallel-arm resonators are commonly connected to the second reference potential terminal 6B, any circuit configuration may be provided. Also, the capacitor C is preferably connected between the first reference potential terminal 6A and the second reference potential terminal 6B. Also, the first reference potential electrode 26A and the first external reference potential electrode 26G are preferably electrically connected to the first reference potential terminal 6A, and the second reference potential electrode 26B and the second external reference potential electrode 26H are preferably electrically connected to the second reference potential terminal 6B. Furthermore, the inductor L is preferably connected between the second reference potential electrode 26B and the second external reference potential electrode 26H.

In the present specification, an inductor may be provided not only by a surface-mounted inductor element or an inductor element provided as a chip component but also by a coil including an electrode, such as a wire, or a meandering wire, for example. An electrode, such as a wire, includes inductance as a parameter.

Specifically, the plurality of resonators of the reception filter 1B include a series-arm resonator S11, a series-arm resonator S12, a series-arm resonator S13, a parallel-arm resonator P11, a parallel-arm resonator P12, and a longitudinally coupled resonator acoustic wave filter 7. In the present example embodiment, all of the resonators of the reception filter 1B other than the longitudinally coupled resonator acoustic wave filter 7 are acoustic wave resonators.

The longitudinally coupled resonator acoustic wave filter 7 is connected between the second input terminal 4B and the second output terminal 5B. The series-arm resonator S11 and the series-arm resonator S12 are connected in series with each other between the second input terminal 4B and the longitudinally coupled resonator acoustic wave filter 7. The series-arm resonator S13 is connected between the longitudinally coupled resonator acoustic wave filter 7 and the second output terminal 5B. The parallel-arm resonator P11 is connected between the reference potential terminal 6C and a connection point between the series-arm resonator S11 and the series-arm resonator S12. The parallel-arm resonator P12 is connected between the second output terminal 5B and the reference potential terminal 6D. The circuit configuration of the reception filter 1B is not limited to the example described above.

The multiplexer 10 includes a plurality of inductors in addition to the inductor L. Specifically, the plurality of inductors include an inductor M1, an inductor M2, and an inductor M3. The inductor M1 is connected between the common connection terminal 2 and the ground potential. The inductor M2 is connected between the reference potential terminal 6C of the reception filter 1B and the reference potential. The inductor M3 is connected between the reference potential terminal 6D of the reception filter 1B and the reference potential. However, the multiplexer 10 does not have to include the inductors other than the inductor L.

FIG. 1 illustrates an example of the outside of the multiplexer 10. Specifically, the inductor M4 is connected between the second output terminal 5B of the reception filter 1B and the reference potential. The inductor M5 is connected to the first input terminal 4A of the transmission filter 1A. A capacitor D is connected between the inductor M5 and the reference potential. However, the configuration of the outside of the multiplexer 10 is not limited to the example described above.

The present example embodiment has the following configuration. 1) The capacitor C is connected between the first reference potential terminal 6A and the second reference potential terminal 6B. 2) The total inductance between the first reference potential electrode 26A and the first external reference potential electrode 26G is less than the total inductance between the second reference potential electrode 26B and the second external reference potential electrode 26H. This makes it possible to increase the out-of-band attenuation of the transmission filter 1A, which is a filter device according to an example embodiment of the present invention. This in turn makes it possible to improve the isolation of the multiplexer 10. These advantageous effects are described below by comparing the present example embodiment with a first comparative example.

A multiplexer 100 according to the first comparative example illustrated in FIG. 2 has the same or substantially the same configuration as the multiplexer 10 of the first example embodiment except that a transmission filter 101A does not include the capacitor C. The isolation in the first example embodiment and the isolation in the first comparative example are compared.

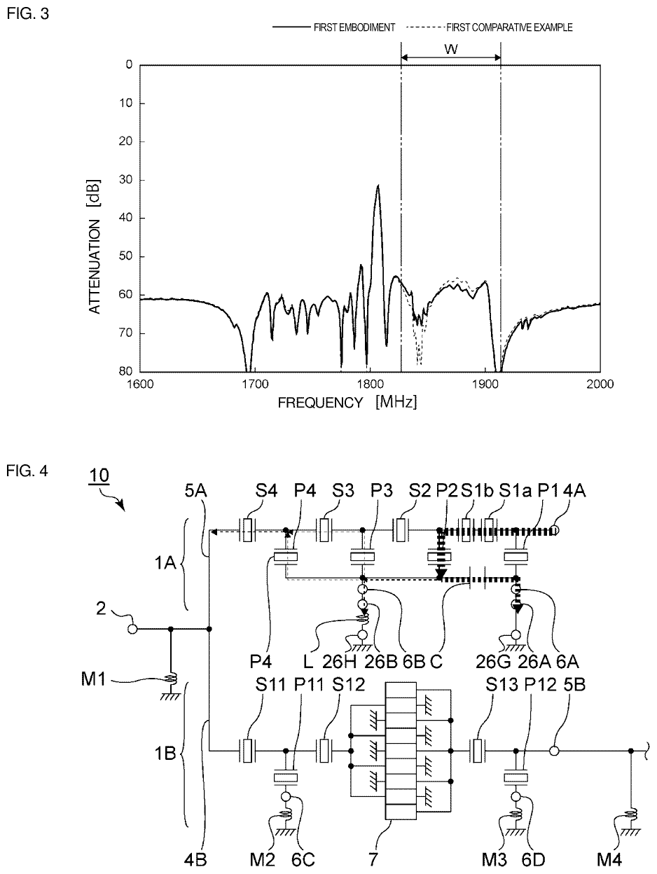

FIG. 3 is a diagram showing isolation of the multiplexers according to the first example embodiment and the first comparative example. The vertical axis in FIG. 3 indicates attenuation. Isolation degrades as the attenuation in the pass band of a filter included in a multiplexer decreases.

As shown in FIG. 3, in a band indicated by a double-headed arrow W, the minimum value of attenuation in the first example embodiment is greater than the minimum value of attenuation in the first comparative example. Thus, the first example embodiment makes it possible to increase the out-of-band attenuation of the transmission filter 1A and thus makes it possible to improve the isolation of the multiplexer 10. The reasons why these advantageous effects can be achieved are described below.

FIG. 4 is a diagram schematically illustrating examples of paths through which portions of a signal are transmitted when the signal is input to the transmission filter according to the first example embodiment.

When a signal is input from the first input terminal 4A of the transmission filter 1A of the first example embodiment, for example, as indicated by a dashed arrow in FIG. 4, a portion of the signal passes through the series-arm resonator S1a, the series-arm resonator S1b, and the parallel-arm resonator P2. The part of the signal passes through the capacitor C and flows outside from the first reference potential terminal 6A. Another portion of the signal flows outside through the second reference potential terminal 6B. On the other hand, a still another portion of the signal may pass through the parallel-arm resonator P3 or the parallel-arm resonator P4 and leak toward the first output terminal 5A instead of flowing outside from the second reference potential terminal 6B. However, the first example embodiment makes it possible to reduce or prevent such leakage. Details of this feature are described below.

The inductance of a portion to which a plurality of parallel-arm resonators are commonly connected tends to be large. For this reason, with the related-art configuration, a portion of a signal tends to leak toward the output terminal without flowing outside from a reference potential terminal to which a plurality of parallel-arm resonators are connected.

The first example embodiment also includes such a configuration. Specifically, a plurality of second parallel-arm resonators, namely, the parallel-arm resonator P2, the parallel-arm resonator P3, and the parallel-arm resonator P4, are connected to the second reference potential terminal 6B. However, in the first example embodiment, in addition to this configuration, the capacitor C is connected between the first reference potential terminal 6A and the second reference potential terminal 6B. Also, the total inductance between the first reference potential electrode 26A and the first external reference potential electrode 26G is smaller than the total inductance between the second reference potential electrode 26B and the second external reference potential electrode 26H. With this configuration, a signal passing through any of the second parallel-arm resonators is more likely to flow toward the first reference potential terminal 6A than toward the second reference potential terminal 6B or other second parallel-arm resonators. This makes it possible to prevent a signal that has passed through a second parallel-arm resonator from leaking toward the first output terminal 5A.

Furthermore, in the first example embodiment, because the capacitor C is connected between the first reference potential terminal 6A and the second reference potential terminal 6B, the attenuation pole can be positioned within the band indicated by the double-headed arrow W in FIG. 3. This makes it possible to increase the out-of-band attenuation of the transmission filter 1A and to effectively improve the isolation of the multiplexer 10.

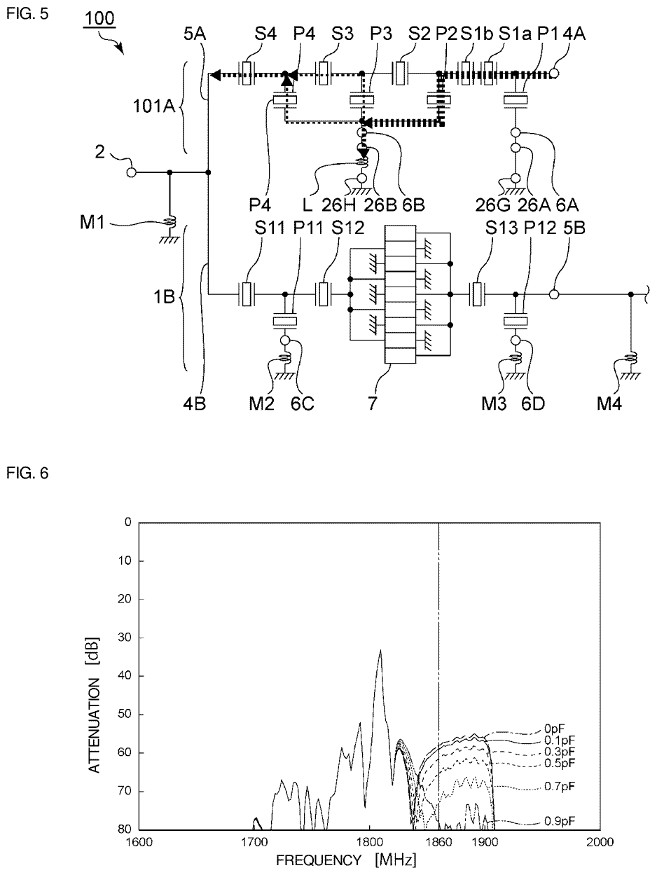

FIG. 5 is a diagram schematically illustrating examples of paths through which portions of a signal are transmitted when the signal is input to a transmission filter according to the first comparative example.

In the first comparative example, the capacitor C is not connected between the first reference potential terminal 6A and the second reference potential terminal 6B. Also, a plurality of second parallel-arm resonators are connected to the second reference potential terminal 6B. Therefore, the total inductance between the second reference potential terminal 6B and the second reference potential electrode 26B and between the second reference potential electrode 26B and the second external reference potential electrode 26H is large. Accordingly, it is not possible to sufficiently prevent a signal that has passed through a second parallel-arm resonator from leaking toward the first output terminal 5A.

In the first example embodiment, the relationship between the electrostatic capacitance of the capacitor C and isolation is derived by simulation. Specifically, for example, the electrostatic capacitance of the capacitor C is set to about 0.1 pF, about 0.3 pF, about 0.5 pF, about 0.7 pF, and about 0.9 pF. As a second comparative example, isolation is also derived by setting the electrostatic capacitance between the first reference potential terminal 6A and the second reference potential terminal 6B to about 0 pF.

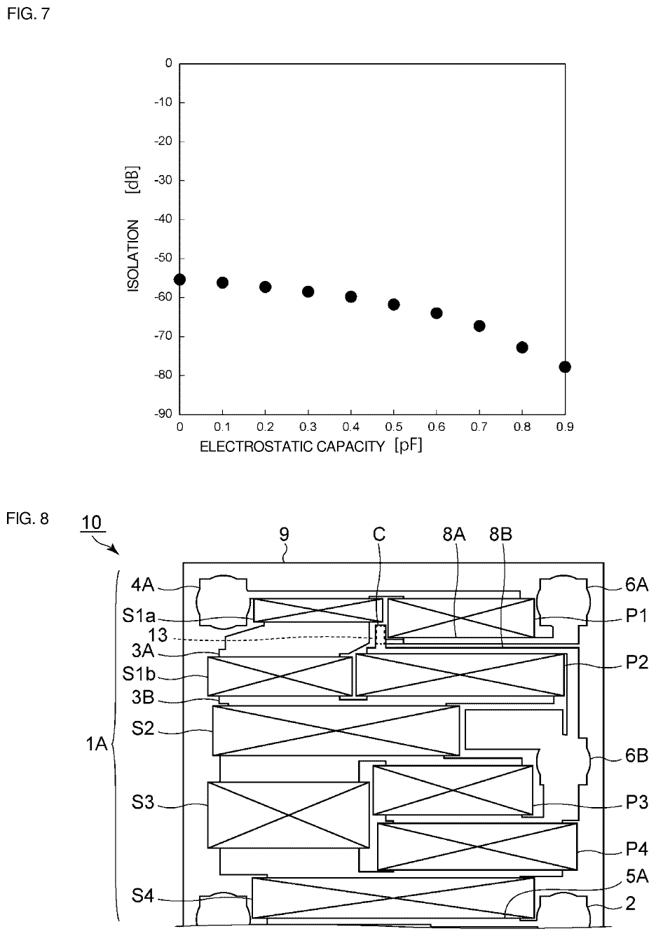

FIG. 6 is a diagram showing a relationship between isolation and the electrostatic capacitance between the first reference potential terminal and the second reference potential terminal. FIG. 7 is a diagram showing a relationship between isolation near 1855 MHz and the electrostatic capacitance between the first reference potential terminal and the second reference potential terminal.

As shown in FIGS. 6 and 7, compared with the second comparative example in which the electrostatic capacitance between the first reference potential terminal 6A and the second reference potential terminal 6B is about 0 pF, the isolation is better in the first example embodiment in which the electrostatic capacitance is greater than 0 pF. Also, in the first example embodiment, the isolation improves as the electrostatic capacitance of the capacitor C increases toward 0.9 pF.

The electrostatic capacitance of the capacitor C is preferably, for example, greater than or equal to about 0.1 pF and more preferably greater than or equal to about 0.3 pF. This makes it possible to further improve the isolation. On the other hand, the electrostatic capacitance is preferably, for example, less than or equal to about 1.0 pF. This makes it possible to prevent an increase in the size of the transmission filter 1A.

Generally, as the size of a multiplexer, such as a duplexer, decreases, the distance between a plurality of filters included in the multiplexer decreases. Therefore, as the size of a multiplexer decreases, the isolation of the multiplexer tends to degrade. In contrast, example embodiments of the present invention make it possible to improve the isolation. Accordingly, example embodiments of the present invention make it easier to reduce the size of a multiplexer.

The configuration of the first example embodiment is described in more detail below.

FIG. 8 is a schematic plan view of the transmission filter according to the first example embodiment. In FIG. 8, each of the series-arm resonators and the parallel-arm resonators is schematically indicated by a rectangle with two diagonals. The same also applies to schematic plan views other than FIG. 8.

The multiplexer 10 includes a piezoelectric substrate 9. Although not illustrated in FIG. 8, the transmission filter 1A and the reception filter 1B of the multiplexer 10 share the same piezoelectric substrate 9. A piezoelectric substrate is a substrate that has piezoelectric properties. In the first example embodiment, the piezoelectric substrate 9 is made solely of a piezoelectric material. Examples of piezoelectric materials include lithium tantalate, lithium niobate, zinc oxide, aluminum nitride, crystal, or lead zirconate titanate (PZT). It is preferable to use, for example, lithium tantalate or lithium niobate as the piezoelectric material. In the first example embodiment, for example, lithium niobate is used as the piezoelectric material. Also, the piezoelectric substrate 9 may be a multilayer substrate including a piezoelectric layer.

In the first example embodiment, all of the resonators of the transmission filter 1A are acoustic wave resonators. Examples of configurations of acoustic wave resonators are described below.

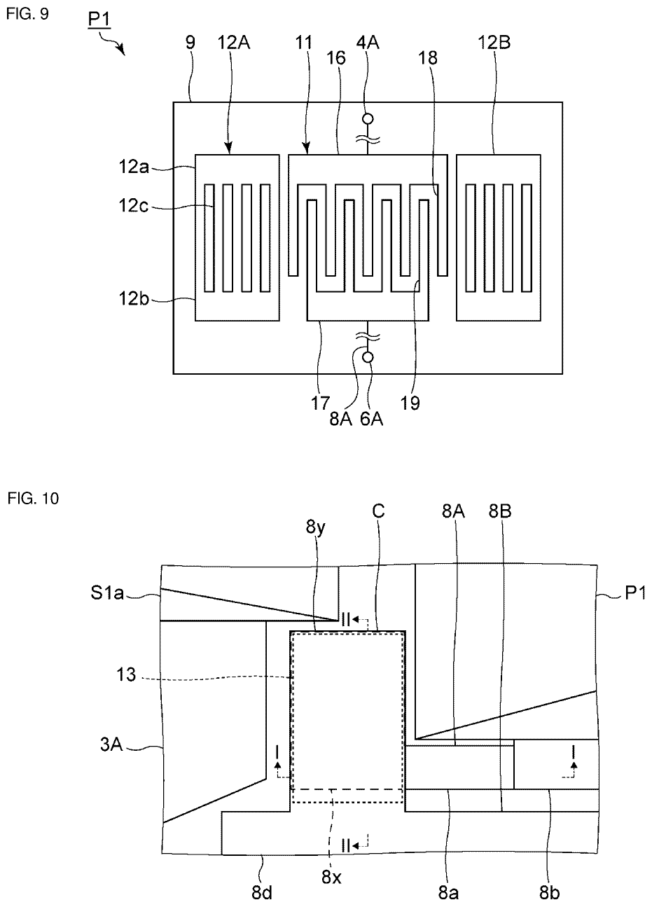

FIG. 9 is a schematic plan view of a series-arm resonator of the transmission filter according to the first example embodiment. In FIG. 9, wires and other components connected to the parallel-arm resonator P1, which is the first parallel-arm resonator, are schematically illustrated.

The parallel-arm resonator P1 includes the piezoelectric substrate 9 and an interdigital transducer (IDT) electrode 11. The IDT electrode 11 is disposed on the piezoelectric substrate 9. The IDT Electrode 11 includes a pair of busbars and a plurality of electrode fingers. Specifically, the pair of busbars includes a first busbar 16 and a second busbar 17. The first busbar 16 and the second busbar 17 are disposed to face each other. Specifically, the plurality of electrode fingers include a plurality of first electrode fingers 18 and a plurality of second electrode fingers 19. A first end of each of the first electrode fingers 18 is connected to the first busbar 16. A first end of each of the plurality of second electrode fingers 19 is connected to the second busbar 17. The plurality of first electrode fingers 18 and the plurality of second electrode fingers 19 are interdigitated with each other. The IDT electrode 11 may include a single-layer metal film or a multilayer metal film.

In the descriptions below, the first busbar 16 and the second busbar 17 as illustrated in FIG. 9 may be collectively referred to as busbars. The first electrode fingers 18 and the second electrode fingers 19 may be collectively referred to as electrode fingers. The direction in which the plurality of electrode fingers extend may be referred to as an electrode finger extension direction, and the direction orthogonal or substantially orthogonal to the electrode finger extension direction may be referred to as an electrode finger orthogonal direction. In the first example embodiment, the electrode finger extension directions of all of the series-arm resonators and parallel-arm resonators of the transmission filter 1A are parallel or substantially parallel to each other. The electrode finger extension direction in FIGS. 8 and 9 is the vertical direction.

As illustrated in FIG. 9, the parallel-arm resonator P1 includes a pair of reflectors. Specifically, the pair of reflectors includes a reflector 12A and a reflector 12B. The reflector 12A and the reflector 12B are disposed on the piezoelectric substrate 9 to face each other across the IDT electrode 11 in the electrode finger orthogonal direction. The reflector 12A includes a pair of busbars and a plurality of electrode fingers 12c. Specifically, the pair of busbars of the reflector 12A include a busbar 12a and a busbar 12b. The busbar 12a and the busbar 12b face each other. A first end of each of the plurality of electrode fingers 12c is connected to the busbar 12a. A second end of each of the plurality of electrode fingers 12c is connected to the busbar 12b. The reflector 12B has the same or substantially the same configuration as the reflector 12A.

Similarly to the parallel-arm resonator P1, each of the parallel-arm resonators and the series-arm resonators, which are other than the parallel-arm resonator P1, of the transmission filter 1A and the reception filter 1B illustrated in FIG. 1 includes an IDT electrode and a pair of reflectors. That is, each of the parallel-arm resonators and the series-arm resonators includes an IDT electrode disposed on the piezoelectric substrate 9. Also, the reflectors are provided to improve the resonance characteristics of each of the parallel-arm resonators and the series-arm resonators.

On the other hand, the longitudinally coupled resonator acoustic wave filter 7 of the reception filter 1B includes nine IDT electrodes and a pair of reflectors. The longitudinally coupled resonator acoustic wave filter 7 includes one stage. Thus, the longitudinally coupled resonator acoustic wave filter 7 includes a plurality of IDT electrodes on the piezoelectric substrate 9. Each of the resonators makes it possible to improve the resonance characteristics of the longitudinally coupled resonator acoustic wave filter 7. However, the number of IDT electrodes and the number of stages of the longitudinally coupled resonator acoustic wave filter 7 are not limited to the examples described above.

In the first example embodiment, all of the resonators of the transmission filter 1A share the same piezoelectric substrate 9. All of the resonators of the reception filter 1B share the same piezoelectric substrate 9. Also, all of the resonators of the transmission filter 1A and all of the resonators of the reception filter 1B share the same piezoelectric substrate 9. Alternatively, for example, the transmission filter 1A and the reception filter 1B may include separate piezoelectric substrates 9.

As illustrated in FIG. 8, the parallel-arm resonator P1 and the parallel-arm resonator P2 are adjacent to each other in the electrode finger extension direction. As described above, the parallel-arm resonator P1 is the first parallel-arm resonator. The parallel-arm resonator P2 is one of the plurality of second parallel-arm resonators.

In terms of circuit configuration, a first reference potential wire 8A is connected to a side of the parallel-arm resonator P1 that is closer to the first reference potential terminal 6A. Specifically, as illustrated in FIG. 8, the first reference potential wire 8A is connected to a busbar of the parallel-arm resonator P1 that is disposed closer to the parallel-arm resonator P2. In the present specification, a reference potential wire indicates a wire that is connected to a reference potential terminal and is also connected to the reference potential. The first reference potential wire 8A is connected to the first reference potential terminal 6A.

On the other hand, in terms of circuit configuration, a second reference potential wire 8B is connected to a side of the parallel-arm resonator P2, i.e., one of the plurality of second parallel-arm resonators, that is closer to the second reference potential terminal 6B. Specifically, as illustrated in FIG. 8, the second reference potential wire 8B is connected to a busbar of the parallel-arm resonator P2 that is disposed closer to the parallel-arm resonator P1. The second reference potential wire 8B is connected to the second reference potential terminal 6B. The first reference potential wire 8A and the second reference potential wire 8B are adjacent to each other in the electrode finger extension direction.

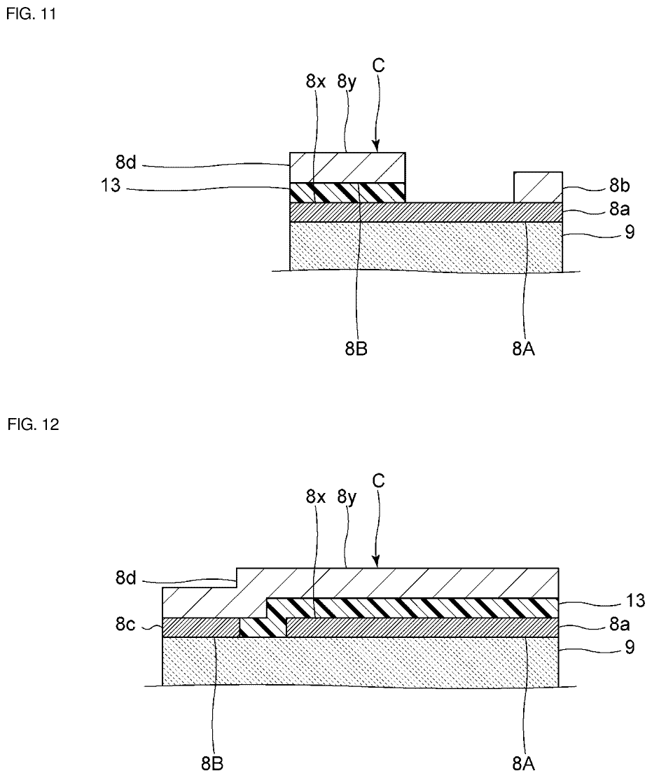

FIG. 10 is an enlarged schematic plan view of a portion around the capacitor of the transmission filter according to the first example embodiment. FIG. 11 is a schematic cross-sectional view taken along line I-I line in FIG. 10. FIG. 12 is a schematic cross-sectional view taken along line II-II in FIG. 10.

As illustrated in FIGS. 10 and 11, the first reference potential wire 8A is a multilayer structure that includes a first layer 8a and a second layer 8b. Specifically, the first layer 8a is disposed on the piezoelectric substrate 9. The second layer 8b is stacked on the first layer 8a. As illustrated in FIG. 12, the second reference potential wire 8B is a multilayer structure that includes a third layer 8c and a fourth layer 8d. Specifically, the third layer 8c is disposed on the piezoelectric substrate 9. The fourth layer 8d is stacked on the third layer 8c. In the descriptions below, each of the direction in which the first layer 8a and the second layer 8b are stacked and the direction in which the third layer 8c and the fourth layer 8d are stacked is referred to as a stacking direction.

In the first example embodiment, the first layer 8a of the first reference potential wire 8A includes a first capacitor forming portion 8x. The fourth layer 8d of the second reference potential wire 8B includes a second capacitor forming portion 8y. The first capacitor forming portion 8x of the first layer 8a and the second capacitor forming portion 8y of the fourth layer 8d face each other across an insulating film 13. This configuration defines the capacitor C.

More specifically, as illustrated in FIG. 11, in the first reference potential wire 8A, the second layer 8b is not stacked on a portion of the first layer 8a. That is, an end portion of the first layer 8a in the electrode finger orthogonal direction extends outward in the electrode finger orthogonal direction beyond an end portion of the second layer 8b in the electrode finger orthogonal direction. The portion of the first layer 8a on which the second layer 8b is not stacked includes the first capacitor forming portion 8x.

As illustrated in FIG. 12, in the second reference potential wire 8B, a portion of the fourth layer 8d is not stacked on the third layer 8c. Specifically, a portion of an end portion of the fourth layer 8d in the electrode finger extension direction extends outward in the electrode finger extension direction beyond an end portion of the third layer 8c in the electrode finger extension direction. The portion of the fourth layer 8d not stacked on the third layer 8c includes a second capacitor forming portion 8y.

The insulating film 13 is disposed on the first capacitor forming portion 8x of the first layer 8a. The second capacitor forming portion 8y of the fourth layer 8d is disposed on the insulating film 13. That is, the first layer 8a and the fourth layer 8d face each other in the stacking direction across the insulating film 13. This configuration defines the capacitor C.

In the first example embodiment, in the first layer 8a, the width of the first capacitor forming portion 8x is greater than the width of a portion adjacent to the first capacitor forming portion 8x. This makes it possible to increase the electrostatic capacitance of the capacitor C. The width of the first layer 8a indicates a dimension of the first layer 8a along a direction that is orthogonal or substantially orthogonal to the direction in which the first layer 8a extends. However, in the first layer 8a, the width of the first capacitor forming portion 8x may be the same or substantially the same as the width of the portion adjacent to the first capacitor forming portion 8x.

The capacitor C is adjacent to the parallel-arm resonator P1, which is the first parallel-arm resonator, in the electrode finger orthogonal direction. The capacitor C is adjacent to the parallel-arm resonator P2, which is one of the plurality of second parallel-arm resonators, in the electrode finger extension direction. These configurations make it possible to simplify the layout of the first reference potential wire 8A and the second reference potential wire 8B. This in turn makes it possible to reduce the size of the multiplexer 10.

The position of the capacitor C is not limited to the example described above. However, the capacitor C is preferably adjacent to at least one of the first parallel-arm resonator and the plurality of second parallel-arm resonators in one of the electrode finger extension direction or the electrode finger orthogonal direction. This makes it possible to simplify the layout of the first reference potential wire 8A or the second reference potential wire 8B.

As in the first example embodiment, the first reference potential wire 8A and the second reference potential wire 8B are preferably disposed adjacent to each other on the piezoelectric substrate 9. This makes it possible to effectively simplify the layout of the first reference potential wire 8A and the second reference potential wire 8B for the capacitor C. This in turn makes it possible to effectively prevent an increase in the size of the multiplexer 10.

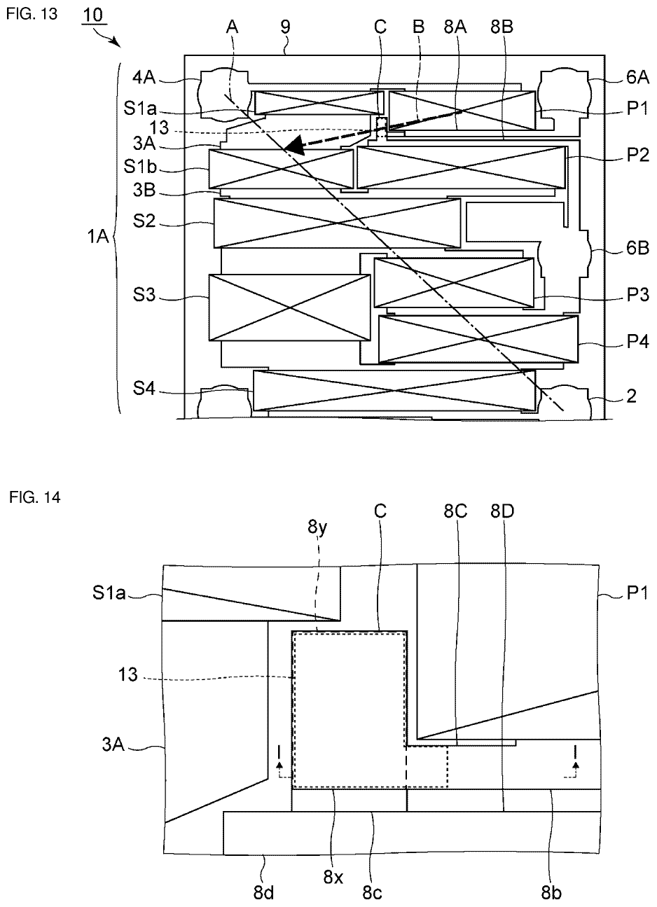

FIG. 13 is a schematic plan view for describing the positional relationship between the first parallel-arm resonator and the capacitor according to the first example embodiment. A dashed-dotted line in FIG. 13 is a virtual line A that connects the common connection terminal 2 and the first input terminal 4A. A dashed arrow B indicates the direction from the center of the parallel-arm resonator P1, which is the first parallel-arm resonator, toward the capacitor C.

In the first example embodiment, the virtual line A is located in the direction indicated by the arrow B when viewed from the center of the parallel-arm resonator P1. Therefore, the capacitor C is located in a vicinity of the virtual line A with reference to the center of the parallel-arm resonator P1. This facilitates further improvement of the isolation. Details of this advantageous effect are described below.

When a signal is input from an input terminal to a transmission filter, a portion of the signal may propagate directly through a piezoelectric substrate without passing through the transmission filter. The signal propagated directly through the piezoelectric substrate may reach a common connection terminal. Such a signal may be referred to as a direct wave. The direct wave reaching the common connection terminal tends to pass through a short path among paths leading from the input terminal to the common connection terminal. Also, a response resulting from the direct wave passing through the short path tends to be large. The frequency at which the response occurs may be located in the pass band of the reception filter. Therefore, the isolation may be degraded due to the direct wave.

In contrast, the capacitor C of the first example embodiment illustrated in FIG. 13 is defined by a portion of the first reference potential wire 8A and a portion of the second reference potential wire 8B. That is, the electrodes defining the capacitor C are connected to the reference potential. Therefore, the capacitor C defines and functions as a shield electrode against the direct wave. In the first example embodiment, the path indicated by the virtual line A is the shortest path among paths from the first input terminal 4A to the common connection terminal 2. As described above, the capacitor C is disposed in a vicinity of the virtual line A. Accordingly, the capacitor C effectively defines and functions as a shield electrode against the direct wave. This makes it easier to improve the isolation.

In terms of circuit configuration, the plurality of second parallel-arm resonators are disposed closer to the first output terminal 5A and the common connection terminal 2 than the first parallel-arm resonator. Here, the portion of the piezoelectric substrate 9 of the plurality of second parallel-arm resonators is also preferably closer to the first output terminal 5A and the common connection terminal 2 than the portion of the piezoelectric substrate 9 of the first parallel-arm resonator. In this case, when viewed from the center of the first parallel-arm resonator, the virtual line A is preferably located in the direction from the center toward the capacitor C. This makes it possible to more reliably improve the isolation.

The configuration of the capacitor C is not limited to the example described above. A first variation and a second variation of the first example embodiment, which differ only in the configuration of the capacitor C from the first example embodiment, are described below. Similarly to the first example embodiment, the first variation and the second variation can also improve the isolation.

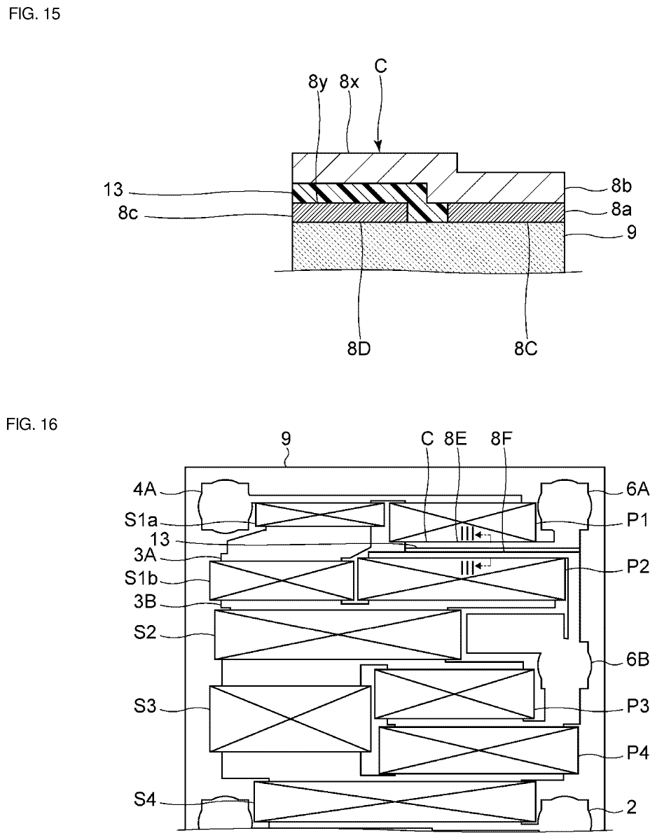

FIG. 14 is an enlarged schematic plan view of a portion around a capacitor of a transmission filter according to the first variation of the first example embodiment. FIG. 15 is the schematic cross-sectional view taken along line I-I in FIG. 14.

As illustrated in FIG. 14, in the present variation, the position of the capacitor C is the same or substantially the same as that in the first example embodiment. However, in the present variation, as illustrated in FIG. 15, a portion of a second layer 8b of a first reference potential wire 8C is not stacked on a first layer 8a. That is, an end portion of the second layer 8b in the electrode finger orthogonal direction extends outward in the electrode finger orthogonal direction beyond an end portion of the first layer 8a in the electrode finger orthogonal direction. The portion of the second layer 8b not stacked on the first layer 8a includes a first capacitor forming portion 8x.

As illustrated in FIG. 14, a fourth layer 8d is not stacked on a portion of a third layer 8c of a second reference potential wire 8D. Specifically, a portion of an end portion of the third layer 8c in the electrode finger extension direction extends outward in the electrode finger extension direction beyond an end portion of the fourth layer 8d in the electrode finger extension direction. The portion of the third layer 8c on which the fourth layer 8d is not stacked includes a second capacitor forming portion 8y.

As illustrated in FIG. 15, an insulating film 13 is disposed on the second capacitor forming portion 8y of the third layer 8c. The first capacitor forming portion 8x of the second layer 8b is disposed on the insulating film 13. That is, the second layer 8b and the third layer 8c face each other in the stacking direction across the insulating film 13. This configuration defines the capacitor C.

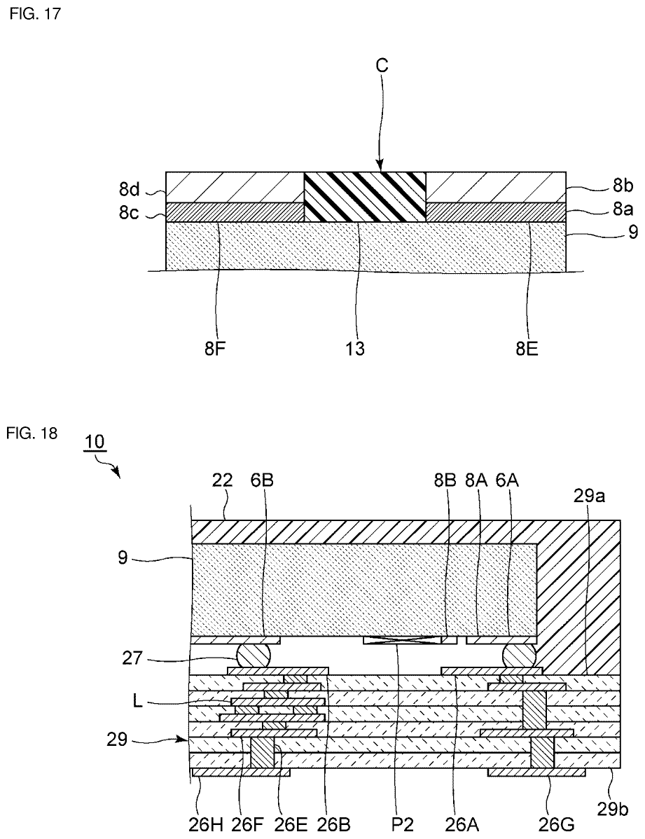

FIG. 16 is a schematic plan view of a transmission filter according to the second variation of the first example embodiment. FIG. 17 is a schematic cross-sectional view taken along line III-III in FIG. 16.

As illustrated in FIG. 16, in the present variation, similarly to the first example embodiment, a first reference potential wire 8E and a second reference potential wire 8F are adjacent to each other in the electrode finger extension direction. As illustrated in FIG. 17, the insulating film 13 is disposed on a portion of the piezoelectric substrate 9 between the first reference potential wire 8E and the second reference potential wire 8F. With this layout, the first reference potential wire 8E and the second reference potential wire 8F face each other in the electrode finger extension direction across the insulating film 13. This configuration defines the capacitor C.

In the present variation, the insulating film 13 is not provided on the first reference potential wire 8E and the second reference potential wire 8F. More specifically, the insulating film 13 is not provided on the surfaces of the first reference potential wire 8E and the second reference potential wire 8F that face the piezoelectric substrate 9. However, the insulating film 13 may be provided over the piezoelectric substrate 9, the first reference potential wire 8E, and the second reference potential wire 8F.

The first reference potential wire 8E and the second reference potential wire 8F are adjacent to each other in the electrode finger extension direction. However, the first reference potential wire 8E and the second reference potential wire 8F may be adjacent to each other in any other direction. For example, the first reference potential wire 8E and the second reference potential wire 8F may be adjacent to each other in the electrode finger orthogonal direction. In example embodiments of the present invention, the first reference potential wire 8E and the second reference potential wire 8F may face each other across the insulating film 13 in a direction that is orthogonal or substantially orthogonal to the stacking direction.

However, as in the first example embodiment illustrated in FIG. 10, it is preferable that the first capacitor forming portion 8x of the first reference potential wire 8A and the second capacitor forming portion 8y of the second reference potential wire 8B face each other in the stacking direction across the insulating film 13. This makes it possible to increase the area of the electrodes of the capacitor C. This in turn enables the electrodes of the capacitor C to effectively define and function as a shield electrode. This also makes it possible to effectively increase the electrostatic capacitance of the capacitor C. Accordingly, it is possible to more reliably increase the out-of-band attenuation of the transmission filter 1A and more reliably improve the isolation of the multiplexer 10.

On the other hand, the capacitor C may have a configuration including an IDT electrode. In this case, the capacitor C includes an IDT electrode on the piezoelectric substrate 9. In this capacitor C, the first reference potential wire 8A is connected to one of busbars of the IDT electrode. The second reference potential wire 8B is connected to the other one of the busbars of the IDT electrode of the capacitor C. The electrode finger extension direction in the capacitor C is preferably orthogonal or substantially orthogonal to the electrode finger extension direction in the first parallel-arm resonator and the plurality of second parallel-arm resonators. It is more preferable that the electrode finger extension direction in the capacitor C is orthogonal or substantially orthogonal to the electrode finger extension directions in all of the resonators. This makes it possible to reduce the influence of the excitation of the acoustic wave by the capacitor C on the filter characteristics.

Even when the capacitor C includes an IDT electrode, it is preferable that the first reference potential wire 8A and the second reference potential wire 8B are disposed adjacent to each other on the piezoelectric substrate 9. This makes it easier to simplify the layout of the first reference potential wire 8A and the second reference potential wire 8B that are connected to the capacitor C. This in turn makes it easier to prevent an increase in the size of the multiplexer 10.

As illustrated in FIG. 1, in terms of circuit configuration in the first example embodiment, the series-arm resonator S1a and the series-arm resonator S1b are disposed closer to the first input terminal 4A compared with the parallel-arm resonator P2, the parallel-arm resonator P3, and the parallel-arm resonator P4, which are the plurality of parallel-arm resonators. As illustrated in FIG. 8, a connection wire 3A is connected to a side of the series-arm resonator S1a that is closer to the first output terminal 5A. The connection wire 3A is also connected to a side of the series-arm resonator S1b that is closer to the first input terminal 4A. Furthermore, a connection wire 3B is connected to a side of the series-arm resonator S1b that is closer to the first output terminal 5A.

In the first example embodiment, the first reference potential wire 8A and the connection wire 3A are adjacent to each other on the piezoelectric substrate 9. Specifically, the first capacitor forming portion 8x of the first reference potential wire 8A and the connection wire 3A are adjacent to each other. This makes it possible to effectively increase the out-of-band attenuation of the transmission filter 1A and to effectively improve the isolation of the multiplexer 10.

Also, a portion of the first reference potential wire 8A other than the first capacitor forming portion 8x may be adjacent to the connection wire 3A. Alternatively, the first reference potential wire 8A and the connection wire 3B may be disposed adjacent to each other on the piezoelectric substrate 9.

As described above, the circuit configuration of the transmission filter 1A is not limited to the circuit configuration of the first example embodiment. However, in terms of circuit configuration, it is preferable to provide at least one series-arm resonator that is disposed closer to the first input terminal 4A than the plurality of second parallel-arm resonators. It is preferable that any of connection wires connected to this series-arm resonator and the first reference potential wire 8A are disposed adjacent to each other on the piezoelectric substrate 9. This makes it possible to effectively increase the out-of-band attenuation of the transmission filter 1A and to effectively improve the isolation of the multiplexer 10.

FIG. 18 is a schematic cross-sectional view showing a cross section that passes through the first reference potential terminal and the second reference potential terminal of the multiplexer according to the first example embodiment. In FIG. 18, an acoustic wave resonator is schematically indicated by a rectangle with two diagonals. The same applies to schematic cross-sectional views other than FIG. 18.

The multiplexer 10 includes a package substrate 29. Specifically, the transmission filter 1A and the reception filter 1B share the package substrate 29. The configuration of the multiplexer 10 corresponds to a configuration in which acoustic wave elements including the piezoelectric substrate 9 are, for example, flip-chip mounted on the package substrate 29.

The multiplexer 10 includes a plurality of conductive connection portions 27 and a sealing resin layer 22. In the first example embodiment, each connection portion 27 is, for example, a bump. Alternatively, the connection portion 27 may be, for example, a conductive adhesive. The plurality of connection portions 27 connect a plurality of terminals provided on the piezoelectric substrate 9 to the package substrate 29. The sealing resin layer 22 is provided on the package substrate 29 to cover the piezoelectric substrate 9.

The package substrate 29 includes a multilayer substrate formed by laminating a plurality of package layers and a plurality of electrodes formed in or on the multilayer substrate. In the first example embodiment, the package substrate 29 includes six package layers, for example. The number of layers of the package substrate 29 only needs to be two or more. Examples of materials of the package layers include glass epoxy resins and ceramic.

Each of the plurality of package layers includes a first major surface and a second major surface. The first major surface and the second major surface of each package layer face each other. Of the first major surface and the second major surface of each package layer, the first major surface is closer to the piezoelectric substrate 9.

Specifically, the plurality of electrodes of the package substrate 29 include a first reference potential electrode 26A, a second reference potential electrode 26B, a plurality of vias 26E, a plurality of internal wires 26F, a first external reference potential electrode 26G, and a second external reference potential electrode 26H. The first reference potential electrode 26A and the second reference potential electrode 26B are provided on a first major surface 29a of a package layer that is closest to the piezoelectric substrate 9. Each via 26E passes through at least one package layer. Each internal wire 26F is provided between adjacent package layers. The first external reference potential electrode 26G and the second external reference potential electrode 26H are provided on a second major surface 29b of a package layer that is farthest from the piezoelectric substrate 9.

The plurality of vias 26E include a via 26E connecting the first reference potential electrode 26A to an internal wire 26F, vias 26E connecting a plurality of internal wires 26F to each other, and a via 26E connecting an internal wire 26F to the first external reference potential electrode 26G. The plurality of vias 26E also include a via 26E connecting the second reference potential electrode 26B to an internal wire 26F and a via 26E connecting an internal wire 26F to the second external reference potential electrode 26H. The first reference potential electrode 26A is connected to the first external reference potential electrode 26G through a plurality of vias 26E and a plurality of internal wires 26F. Similarly, the second reference potential electrode 26B is connected to the second external reference potential electrode 26H through a plurality of vias 26E and a plurality of internal wires 26F.

The first external reference potential electrode 26G and the second external reference potential electrode 26H are electrically connected to an external reference potential. The plurality of electrodes of the package substrate 29 also include electrodes electrically connected to a signal potential and electrodes electrically connected to the reference potential, which are not illustrated in the drawings.

The plurality of connection portions 27 connect a plurality of electrodes provided on the first major surface 29a of the package layer closest to the piezoelectric substrate 9 to a plurality of terminals provided on the piezoelectric substrate 9. Specifically, for example, the plurality of connection portions 27 include a connection portion 27 connecting the first reference potential terminal 6A to the first reference potential electrode 26A and a connection portion 27 connecting the second reference potential terminal 6B to the second reference potential electrode 26B. The plurality of connection portions 27 also include connection portions 27 not illustrated in FIG. 18 that connect electrodes provided on the first major surface 29a to terminals provided on the piezoelectric substrate 9.

The first reference potential terminal 6A is electrically connected to an external reference potential through the connection portion 27, the first reference potential electrode 26A, a plurality of vias 26E, a plurality of internal wires 26F, and the first external reference potential electrode 26G. The second reference potential terminal 6B is electrically connected to the external reference potential through the connection portion 27, the second reference potential electrode 26B, a plurality of vias 26E, a plurality of internal wires 26F, and the second external reference potential electrode 26H. Similarly, the common connection terminal 2, the first input terminal 4A, and the second output terminal 5B illustrated in FIG. 1 are also electrically connected to an external signal potential through a plurality of electrodes on or in the package substrate 29.

In the first example embodiment, the inductor L connected between the second reference potential electrode 26B and the second external reference potential electrode 26H is a coil defined by a plurality of vias 26E and a plurality of internal wires 26F.

Even when no inductor, such as a coil, is connected between the first reference potential electrode 26A and the first external reference potential electrode 26G, a plurality of electrodes connected between the first reference potential electrode 26A and the first external reference potential electrode 26G have inductance as a parameter. However, the inductance of each electrode not defined by, for example, a coil is small. This makes it possible to further increase the difference between the total inductance between the second reference potential electrode 26B and the second external reference potential electrode 26H and the total inductance between the first reference potential electrode 26A and the first external reference potential electrode 26G. This in turn makes it possible to more reliably increase the out-of-band attenuation of the transmission filter 1A and more reliably improve the isolation of the multiplexer 10.

However, the configuration of the inductor L is not limited to the above example. As another example, the inductor L may be a meandering wire provided on the piezoelectric substrate 9. The inductor L may be an internal wire 26F with a meandering shape included in the package substrate 29. The inductor L may include a wire with a meandering shape and the coil described above. Alternatively, the inductor L may be a surface-mounted inductor element or an inductor element provided as a chip element.

The inductor M1, the inductor M2, and the inductor M3 illustrated in FIG. 1 may be provided by a plurality of electrodes in the package substrate 29 illustrated in FIG. 18 or may be provided by surface-mounted elements or chip components. The inductor M4, the inductor M5, and the capacitor D, which are disposed outside the multiplexer 10, may be provided, for example, in the package substrate 29 or in a substrate other than the package substrate 29.

The multiplexer 10 does not have to include the package substrate 29. In this case, the electrodes between the first reference potential electrode 26A and the first external reference potential electrode 26G may be wires and terminals provided on the piezoelectric substrate 9. Similarly, the electrodes between the second reference potential electrode 26B and the second external reference potential electrode 26H may be wires and terminals provided on the piezoelectric substrate 9. In this case, the inductor L may be provided by, for example, a wire with a meandering shape on the piezoelectric substrate 9.

An inductor, such as a coil, may be connected between the first reference potential electrode 26A and the first external reference potential electrode 26G. This example is described in a second example embodiment of the present invention. In the descriptions below, an inductor connected between the first reference potential electrode 26A and the first external reference potential electrode 26G may be referred to as a first inductor. An inductor connected between the second reference potential electrode 26B and the second external reference potential electrode 26H may be referred to as a second inductor.

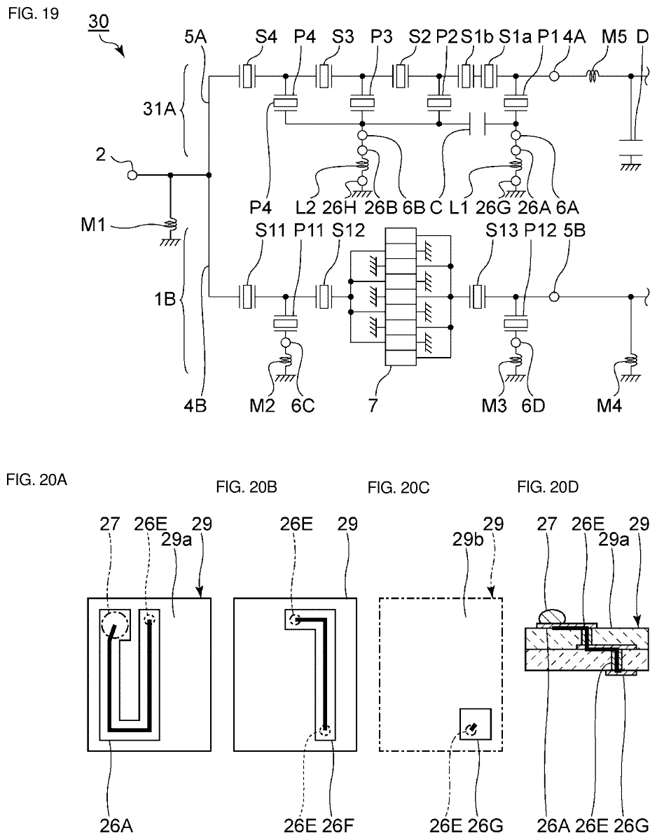

FIG. 19 is a circuit diagram of a multiplexer according to the second example embodiment.

The present example embodiment differs from the first example embodiment in that a first inductor L1 is connected to a parallel-arm resonator P1 of a transmission filter 31A. A second inductor L2 is connected to a parallel-arm resonator P2, a parallel-arm resonator P3, and a parallel-arm resonator P4. The second inductor L2 corresponds to the inductor L in the first example embodiment. Except for the above difference, a multiplexer 30 of the present example embodiment has the same or substantially the same configuration as that of the multiplexer 10 of the first example embodiment.

In the present example embodiment, the inductance of the first inductor L1 is less than the inductance of the second inductor L2. Therefore, the total inductance between the first reference potential electrode 26A and the first external reference potential electrode 26G is less than the total inductance between the second reference potential electrode 26B and the second external reference potential electrode 26H. Accordingly, similarly to the first example embodiment, the present example embodiment makes it possible to increase the out-of-band attenuation of the transmission filter 31A and to improve the isolation of the multiplexer 30.

In the present example embodiment, the first inductor L1 and the second inductor L2 are coils that include a plurality of vias 26E and a plurality of internal wires 26F that are shown in FIG. 18. In the descriptions below, the plurality of vias 26E and the plurality of internal wires 26F of the first inductor L1 or the second inductor L2 may be collectively referred to as wires of the first inductor L1 or the second inductor L2.

The length of wires of the first inductor L1 is less than the length of wires of the second inductor L2. In other words, the total length of a plurality of vias 26E and a plurality of internal wires 26F of the first inductor L1 is less than the total length of a plurality of vias 26E and a plurality of internal wires 26F of the second inductor L2. Accordingly, the inductance of the first inductor L1 is less than the inductance of the second inductor L2.

Below, examples of methods for comparing inductance values are described in more detail. For example, when the widths of internal wires 26F to be compared are the same or substantially the same, the lengths of the internal wires 26F may be compared as described above. Here, the width of each internal wire 26F is the dimension of the internal wire 26F along a direction that is orthogonal or substantially orthogonal to the direction in which the internal wire 26F extends. However, the direction in which an internal wire 26F extends may differ for each portion of the internal wire 26F. Examples of methods for measuring the lengths of a plurality of electrodes in the package substrate 29 are described below with reference to FIGS. 20A to 20D.

FIGS. 20A and 20B are schematic plan views for describing examples of methods for measuring the total length of a plurality of electrodes. FIG. 20C is a schematic transparent plan view for describing an example of a method for measuring the total length of a plurality of electrodes. FIG. 20D is a schematic cross-sectional view for describing an example of a method for measuring the total length of a plurality of electrodes. Here, FIGS. 20A to 20C illustrate examples for the same package substrate 29. FIG. 20D illustrates an example for a package substrate 29 that is different from the package substrate 29 in FIGS. 20A to 20C.

In the example illustrated in FIG. 20A, the first reference potential electrode 26A is provided on the first major surface 29a of the package substrate 29 that is closest to the piezoelectric substrate. In this example, the first reference potential electrode 26A includes a portion provided as an electrode pad and a portion provided as a wire. A connection portion 27 is connected to the portion of the first reference potential electrode 26A that is provided as an electrode pad. A via 26E is connected to the other portion of the first reference potential electrode 26A.

In this case, the length from the center of the portion of the first reference potential electrode 26A connected to the connection portion 27 to the widthwise center of the portion provided as a wire is measured. Regarding the portion provided as a wire, the length of a path passing through the widthwise center of the portion is measured. The end point of the path is the center of the portion of the first reference potential electrode 26A that is connected to the via 26E. Here, it is assumed that the length of the via 26E is the total thickness of the package layers that the via 26E penetrates.

In the example illustrated in FIG. 20B, an internal wire 26F is provided between adjacent package layers. The internal wire 26F is connected to a via 26E penetrating a package layer that is closer to the piezoelectric substrate and a via 26E penetrating a package layer that is farther from the piezoelectric substrate. For the internal wire 26F, the length of a path passing through the widthwise center of the internal wire 26F is measured. Each of the start point and the end point of the path is the center of a portion connected to the via 26E.

In the example illustrated in FIG. 20C, the first external reference potential electrode 26G is provided on the second major surface 29b of a package layer of the package substrate 29 that is farthest from the piezoelectric substrate. In this example, the first external reference potential electrode 26G is provided as an electrode pad. The first external reference potential electrode 26G is connected to a via 26E. In this case, the length from the center of a portion of the first external reference potential electrode 26G connected to the via 26E to the center of the first external reference potential electrode 26G is measured.

In the example illustrated in FIG. 20D, the total length of a plurality of electrodes may be measured in the same or substantially the same manner as in the examples illustrated in FIGS. 20A to 20C.

On the other hand, when the widths of internal wires 26F to be compared differ greatly from each other, inductance values may be obtained by an electromagnetic field simulation using, for example, a finite element method incorporating the materials of the package substrate 29 and the materials of the plurality of electrodes, and then the obtained inductance values may be compared.

For example, the first inductor L1 and the second inductor L2 may be wires with a meandering shape. In this case, the length of the wire defining the first inductor L1 only needs to be less than the length of the wire defining the second inductor L2.

In the first example embodiment and the present example embodiment, three second parallel-arm resonators are provided. In example embodiments of the present invention, at least two second parallel-arm resonators need to be provided. However, for example, three or more second parallel-arm resonators are preferably provided. In this case, the total inductance between the second reference potential terminal 6B and the second reference potential electrode 26B and between the second reference potential electrode 26B and the second external reference potential electrode 26H tends to increase. Therefore, a signal that has passed through any of the second parallel-arm resonators tends to leak particularly toward the first output terminal 5A. In contrast, in example embodiments of the present invention, a signal that has passed through a second parallel-arm resonator can be directed to the capacitor C and the first reference potential terminal 6A. Therefore, example embodiments of the present invention are particularly suitable for a configuration in which three or more second parallel-arm resonators are provided.

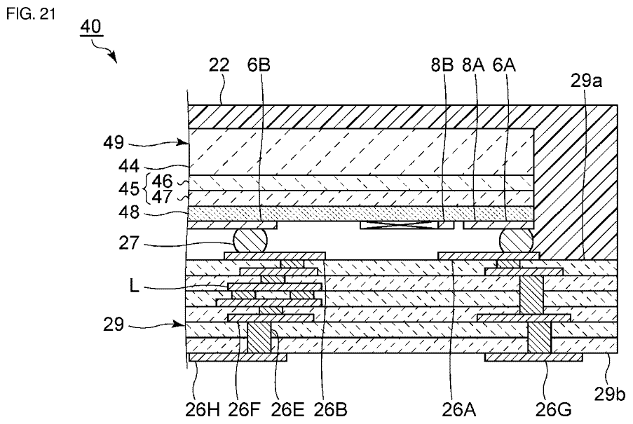

FIG. 21 is a schematic cross-sectional view showing a cross section that passes through a first reference potential terminal and a second reference potential terminal of a multiplexer according to a third example embodiment of the present invention.

The present example embodiment differs from the first example embodiment in that a piezoelectric substrate 49 is a multilayer substrate. Except for this difference, the multiplexer 40 of the present example embodiment has the same or substantially the same configuration as that of the multiplexer 10 of the first example embodiment.

The piezoelectric substrate 49 includes a support substrate 44, an intermediate layer 45, and a piezoelectric layer 48. The intermediate layer 45 includes a first intermediate layer 46 and a second intermediate layer 47. The first intermediate layer 46 is disposed on the support substrate 44. The second intermediate layer 47 is disposed on the first intermediate layer 46. The piezoelectric layer 48 is disposed on the second intermediate layer 47. The layer configuration of the piezoelectric substrate 49 is not limited to the example described above. As another example, the intermediate layer 45 may be a single dielectric layer.

The IDT electrodes, reflectors, terminals, and wires of the resonators of the transmission filter and the reception filter are provided on the piezoelectric layer 48 of the piezoelectric substrate 49.

The circuit configuration of the present example embodiment is the same or substantially the same as that of the first example embodiment. Also, the total inductance between the first reference potential electrode 26A and the first external reference potential electrode 26G is less than the total inductance between the second reference potential electrode 26B and the second external reference potential electrode 26H. Accordingly, the present example embodiment makes it possible to increase the out-of-band attenuation of the transmission filter and to improve the isolation of the multiplexer 40.

Examples of materials of the respective layers of the piezoelectric substrate 49 illustrated in FIG. 21 are described below. In the present specification, a main component refers to a component that accounts for more than 50 weight percent. The material of a main component may exist, for example, in any of a single-crystal, polycrystalline, or amorphous state or in a state in which these are mixed.

Examples of materials usable for the support substrate 44 include piezoelectric materials, such as aluminum nitride, lithium tantalate, lithium niobate, or crystal, ceramics, such as alumina, sapphire, magnesia, silicon nitride, silicon carbide, zirconia, cordierite, mullite, steatite, forsterite, spinel, or sialon, dielectrics, such as aluminum oxide, silicon oxynitride, diamond-like carbon (DLC), or diamond, semiconductors, such as silicon, and materials each including any of the above materials as a main component. Spinel described above includes, for example, an aluminum compound that includes oxygen and one or more elements of Mg, Fe, Zn, or Mn. Examples of spinel include MgAl₂O₄, FeAl₂O₄, ZnAl₂O₄, or MnAl₂O₄. This also applies to “spinel” that is cited as an example of a material of the first intermediate layer 46 described later.

The first intermediate layer 46 of the intermediate layer 45 is a high-acoustic-velocity film. A high-acoustic-velocity film has a relatively high acoustic velocity. More specifically, the acoustic velocity of a bulk wave propagating through a high-acoustic-velocity film is higher than the acoustic velocity of an acoustic wave propagating through the piezoelectric layer 48. Examples of materials usable for the first intermediate layer 46, which is a high-acoustic-velocity film, include piezoelectric materials, such as aluminum nitride, lithium tantalate, lithium niobate, or crystal, ceramics, such as alumina, sapphire, magnesia, silicon nitride, silicon carbide, zirconia, cordierite, mullite, steatite, forsterite, spinel, or sialon, dielectrics, such as aluminum oxide, silicon oxynitride, diamond-like carbon (DLC), or diamond, semiconductors, such as silicon, and materials each including any of the above materials as a main component.

The second intermediate layer 47 of the intermediate layer 45 is a low-acoustic-velocity film. A low-acoustic-velocity film has a relatively low acoustic velocity. More specifically, the acoustic velocity of a bulk wave propagating through a low-acoustic-velocity film is lower than the acoustic velocity of a bulk wave propagating through the piezoelectric layer 48. Examples of materials usable for the second intermediate layer 47, which is a low-acoustic-velocity film, include dielectrics, such as glass, silicon oxide, silicon oxynitride, lithium oxide, tantalum oxide, or compounds including the addition of fluorine, carbon, or boron to silicon oxide, and materials each including any of the above materials as a main component.

As materials of the piezoelectric layer 48, the piezoelectric materials exemplified above can be used. For example, lithium tantalate or lithium niobate is preferably used as the material of the piezoelectric layer 48.

In the piezoelectric substrate 49 of the present example embodiment, the first intermediate layer 46, which is a high-acoustic-velocity film, the second intermediate layer 47, which is a low-acoustic-velocity film, and the piezoelectric layer 48 are laminated in this order. This makes it possible to effectively confine the energy of an acoustic wave to the side of the piezoelectric layer 48.

In the piezoelectric substrate 49, the piezoelectric layer 48 is disposed indirectly on the support substrate 44 via the intermediate layer 45. Alternatively, the piezoelectric layer 48 may be disposed directly on the support substrate 44. Even in this case, it is possible to effectively confine the energy of an acoustic wave to the side of the piezoelectric layer 48. This also makes it possible to improve the isolation.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multiplexer comprising:
a transmission filter including:
an input terminal and an output terminal;
a first reference potential terminal and a second reference potential terminal connected to a reference potential;
a first parallel-arm resonator connected to the first reference potential terminal;
a plurality of second parallel-arm resonators located closer to the output terminal than the first parallel-arm resonator and commonly connected to the second reference potential terminal;
a capacitor connected between the first reference potential terminal and the second reference potential terminal;
a first reference potential electrode connected to the first reference potential terminal and located closer to the reference potential than the capacitor;
a first external reference potential electrode electrically connected to the first reference potential electrode;
a second reference potential electrode connected to the second reference potential terminal and located closer to the reference potential than the capacitor;
a second external reference potential electrode electrically connected to the second reference potential electrode; and
an inductor connected between the second reference potential electrode and the second external reference potential electrode; and
a reception filter; wherein
a total inductance between the first reference potential electrode and the first external reference potential electrode is less than a total inductance between the second reference potential electrode and the second external reference potential electrode.

2. The multiplexer according to claim 1, wherein
the transmission filter further includes:
a first reference potential wire connected to a side of the first parallel-arm resonator closer to the first reference potential terminal than another side of the first parallel-arm resonator in a circuit configuration;
a second reference potential wire connected to a side of one of the plurality of second parallel-arm resonators closer to the second reference potential terminal than another side of the one of the plurality of second parallel-arm resonators; and
an insulating film located between the first reference potential wire and the second reference potential wire; and
the capacitor includes the first reference potential wire and the second reference potential wire that face each other across the insulating film.

3. The multiplexer according to claim 2, wherein
the first reference potential wire includes a multilayer structure including a first layer and a second layer stacked on the first layer;
the second reference potential wire includes a multilayer structure including a third layer and a fourth layer stacked on the third layer; and
when a direction in which the first layer and the second layer of the first reference potential wire are stacked and a direction in which the third layer and the fourth layer of the second reference potential wire are stacked are denoted as a stacking direction, the capacitor includes a configuration in which the first layer and the fourth layer face each other in the stacking direction across the insulating film or a configuration in which the second layer and the third layer face each other in the stacking direction across the insulating film.

4. The multiplexer according to claim 3, further comprising:
a common connection terminal to which the transmission filter and the reception filter are commonly connected; wherein
when viewed from a center of the first parallel-arm resonator, a virtual line connecting the input terminal of the transmission filter to the common connection terminal extends in a direction from the center toward the capacitor.

5. The multiplexer according to claim 1, wherein
the transmission filter further includes a piezoelectric substrate;
each of the first parallel-arm resonator, the plurality of second parallel-arm resonators, and the capacitor is on the piezoelectric substrate and includes an interdigital electrode including a plurality of electrode fingers; and
when an electrode finger extension direction denotes a direction in which the plurality of electrode fingers extend in each of the first parallel-arm resonator, the plurality of second parallel-arm resonators, and the capacitor, the electrode finger extension direction in the capacitor is orthogonal or substantially orthogonal to the electrode finger extension direction in the first parallel-arm resonator and the plurality of second parallel-arm resonators.

6. The multiplexer according to claim 1, wherein
the transmission filter further includes:
a piezoelectric substrate;
a first reference potential wire connected to a side of the first parallel-arm resonator located closer to the first reference potential terminal than another side of the first parallel-arm resonator in a circuit configuration; and
a second reference potential wire connected to a side of one of the plurality of second parallel-arm resonators located closer to the second reference potential terminal than another side of the one of the plurality of second parallel-arm resonators; and
the first reference potential wire and the second reference potential wire are adjacent to each other on the piezoelectric substrate.

7. The multiplexer according to claim 1, wherein
the transmission filter further includes:
a piezoelectric substrate;
at least one series-arm resonator located closer to the input terminal than the plurality of second parallel-arm resonators in terms of circuit configuration;
a first reference potential wire connected to a side of the first parallel-arm resonator located closer to the first reference potential terminal than another side of the first parallel-arm resonator; and
a connection wire connected to the series-arm resonator; and
the first reference potential wire and the connection wire are adjacent to each other on the piezoelectric substrate.

8. The multiplexer according to claim 1, wherein the plurality of second parallel-arm resonators include three or more second parallel-arm resonators.

9. The multiplexer according to claim 1, wherein
the transmission filter further includes a first inductor connected between the first reference potential electrode and the first external reference potential electrode;
the inductor connected between the second reference potential electrode and the second external reference potential electrode is a second inductor;
each of the first inductor and the second inductor includes a wire; and
a length of the wire of the first inductor is less than a length of the wire of the second inductor.

10. The multiplexer according to claim 5, wherein the piezoelectric substrate includes lithium tantalate or lithium niobate.

11. The multiplexer according to claim 7, wherein the piezoelectric substrate includes lithium tantalate or lithium niobate.

12. A filter device comprising:
an input terminal and an output terminal;
a first reference potential terminal and a second reference potential terminal connected to a reference potential;
a first parallel-arm resonator connected to the first reference potential terminal;
plurality of second parallel-arm resonators located closer to the output terminal than the first parallel-arm resonator in terms of circuit configuration and commonly connected to the second reference potential terminal;
a capacitor connected between the first reference potential terminal and the second reference potential terminal;
a first reference potential electrode connected to the first reference potential terminal and located closer to the reference potential than the capacitor;
a first external reference potential electrode electrically connected to the first reference potential electrode;
a second reference potential electrode connected to the second reference potential terminal and located closer to the reference potential than the capacitor;
a second external reference potential electrode electrically connected to the second reference potential electrode; and
an inductor connected between the second reference potential electrode and the second external reference potential electrode; wherein
a total inductance between the first reference potential electrode and the first external reference potential electrode is less than a total inductance between the second reference potential electrode and the second external reference potential electrode.

13. The filter device according to claim 12, further comprising:
a first reference potential wire connected to a side of the first parallel-arm resonator closer to the first reference potential terminal than another side of the first parallel-arm resonator in a circuit configuration;
a second reference potential wire connected to a side of one of the plurality of second parallel-arm resonators closer to the second reference potential terminal than another side of the one of the plurality of second parallel-arm resonators; and
an insulating film located between the first reference potential wire and the second reference potential wire; wherein
the capacitor includes the first reference potential wire and the second reference potential wire that face each other across the insulating film.

14. The filter device according to claim 13, wherein
the first reference potential wire includes a multilayer structure including a first layer and a second layer stacked on the first layer;
the second reference potential wire includes a multilayer structure including a third layer and a fourth layer stacked on the third layer; and
when a direction in which the first layer and the second layer of the first reference potential wire are stacked and a direction in which the third layer and the fourth layer of the second reference potential wire are stacked are denoted as a stacking direction, the capacitor includes a configuration in which the first layer and the fourth layer face each other in the stacking direction across the insulating film or a configuration in which the second layer and the third layer face each other in the stacking direction across the insulating film.

15. The filter device according to claim 12, further comprising:
a piezoelectric substrate; wherein
each of the first parallel-arm resonator, the plurality of second parallel-arm resonators, and the capacitor is on the piezoelectric substrate and includes an interdigital electrode including a plurality of electrode fingers; and
when an electrode finger extension direction denotes a direction in which the plurality of electrode fingers extend in each of the first parallel-arm resonator, the plurality of second parallel-arm resonators, and the capacitor, the electrode finger extension direction in the capacitor is orthogonal or substantially orthogonal to the electrode finger extension direction in the first parallel-arm resonator and the plurality of second parallel-arm resonators.

16. The filter device according to claim 12, further comprising:
a piezoelectric substrate;
a first reference potential wire connected to a side of the first parallel-arm resonator located closer to the first reference potential terminal than another side of the first parallel-arm resonator in a circuit configuration; and
a second reference potential wire connected to a side of one of the plurality of second parallel-arm resonators located closer to the second reference potential terminal than another side of the one of the plurality of second parallel-arm resonators; wherein
the first reference potential wire and the second reference potential wire are adjacent to each other on the piezoelectric substrate.

17. The filter device according to claim 12, further comprising:
a piezoelectric substrate;
at least one series-arm resonator located closer to the input terminal than the plurality of second parallel-arm resonators in terms of circuit configuration;
a first reference potential wire connected to a side of the first parallel-arm resonator located closer to the first reference potential terminal than another side of the first parallel-arm resonator; and
a connection wire connected to the series-arm resonator; wherein
the first reference potential wire and the connection wire are adjacent to each other on the piezoelectric substrate.

18. The filter device according to claim 12, wherein the plurality of second parallel-arm resonators include three or more second parallel-arm resonators.

19. The filter device according to claim 12, further comprising:
a first inductor connected between the first reference potential electrode and the first external reference potential electrode; wherein
the inductor connected between the second reference potential electrode and the second external reference potential electrode is a second inductor;
each of the first inductor and the second inductor is provided by a wire; and
a length of the wire of the first inductor is less than a length of the wire of the second inductor.

20. The filter device according to claim 15, wherein the piezoelectric substrate includes lithium tantalate or lithium niobate.
